(19) United States
(12) Patent Application Publication
(10) Pub. No.: US 2024/0429962 A1
(43) Pub. Date: Dec. 26, 2024

(54) GATE-TO-CASCODE COUPLED INDUCTOR-BASED LNA FOR NOISE REDUCTION AND NEUTRALIZATION

(71) Applicant: Apple Inc., Cupertino, CA (US)

(72) Inventors: Hongrui Wang, San Jose, CA (US); Abbas Komijani, Mountain View, CA (US); Ali Parsa, Poway, CA (US)

(21) Appl. No.: 18/214,307

(22) Filed: Jun. 26, 2023

(51) Int. Cl. H04B 1/40; H03F 3/24

(52) U.S. Cl. CPC H04B 1/40; H03F 3/245; H03F 2200/294; H03F 2200/451; H04B 7/04

(57) ABSTRACT

In some source degeneration-based cascode LNAs, a cascode transistor may contribute a large portion of noise at mmWave frequencies due to lower output impedance from a bottom transistor (e.g., amplifying transistor or transconductance transistor) of the cascode. The cascode noise may negatively impact performance of the LNA. A first inductor (e.g., cascode inductor) may be coupled to the source of the cascode transistor and a second inductor (e.g., notch inductor) may be coupled to the gate of the bottom transistor such that the cascode inductor and a notch inductor inductively couple to each other, introducing a reverse-transmission zero in-band to reduce or eliminate cascode noise contribution and neutralize gate-drain capacitance of the bottom transistor with minimal area consumption.

### BACKGROUND

The present disclosure relates generally to wireless communication, and more specifically to reducing noise in low-noise amplifiers (LNAs).

In some source degeneration-based cascode LNAs, a cascode transistor may contribute excessive noise at millimeter-wave (mmWave) frequencies due to lower output impedance from another (e.g., bottom-disposed) transistor of a cascode LNA. The cascode noise may negatively impact performance of the LNA.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a device includes a plurality of antennas; a transmitter coupled to the plurality of antennas; and a receiver coupled to the plurality of antennas, the receiver including a low-noise amplifier (LNA), including a first transistor, a first inductor coupled to a first source terminal of the first transistor; a second transistor comprising a drain terminal coupled to the first source terminal of the first transistor and the first inductor, a gate terminal coupled to at least one antenna of the plurality of antennas and comprising an input terminal, and a second source terminal, and a second inductor coupled to the gate terminal of the second transistor, the second inductor overlapping the first inductor.

In another embodiment, a low-noise amplifier (LNA) includes a first transistor; a first inductor coupled to a first source terminal of the first transistor and coupled to ground; a second transistor including a drain terminal coupled to the first source terminal of the first transistor and the first inductor, a gate terminal including an input terminal, and a second inductor coupled to the gate terminal of the second transistor, the second inductor configured to inductively couple to the first inductor.

In yet another embodiment, an amplifier includes a first transistor, including a first source terminal, a second transistor, including a drain terminal, a gate terminal, wherein the gate terminal is configured as an input terminal, and a second source terminal, a first inductor coupled at a first inductor terminal to the first source terminal and the drain terminal; and a second inductor coupled at a third inductor terminal to the gate terminal and at a second inductor terminal to a capacitor, wherein the second inductor is configured to couple to the first inductor.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a circuit diagram of a cascode amplifier that reduces or eliminates cascode noise with reduced or minimal area consumption, according to embodiments of the present disclosure;

FIG. 6 is a schematic diagram representing a small signal equivalent circuit model of the cascode amplifier of FIG. 5, according to embodiments of the present disclosure;

FIG. 7 is a layout diagram illustrating the cascode of FIG. 5, according to embodiments of the present disclosure;

FIG. 8 is a plot illustrating noise factor of the cascode amplifier of FIG. 5 as a function of an input signal frequency in a circuit with cascode resonance and neutralization and in a circuit without cascode resonance and neutralization, according to embodiments of the present disclosure;

FIG. 9 is a plot illustrating amplifier stability of the cascode amplifier of FIG. 5 as a function of input signal frequency in a circuit with neutralization and without neutralization, according to embodiments of the present disclosure;

FIG. 10 is a circuit diagram of an alternative cascode amplifier that reduces or eliminates cascode noise with reduced or minimal area consumption, according to embodiments of the present disclosure;

FIG. 11 illustrates a circuit diagram of a cascode amplifier that reduces or eliminates cascode noise with reduced or minimal area consumption via inductive coupling between a cascode inductor and a gate inductor, according to embodiments of the present disclosure; and

FIG. 12 is a circuit diagram of a differential cascode amplifier illustrating how inductive coupling may be used to reduce or neutralize cascode noise in the differential cascode amplifier, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

In some source degeneration-based cascode LNAs, a cascode transistor may contribute excessive noise at millimeter wave (mmWave) frequencies due to lower output impedance from another (e.g., bottom-disposed) transistor (e.g., amplifying transistor or transconductance transistor) of the cascode LNA. The cascode noise may negatively impact performance of the LNA. A first inductor (e.g., cascode inductor) may be coupled to a source terminal of the cascode transistor and a second inductor (e.g., notch inductor) may be coupled to a gate terminal of the other (e.g., bottom) transistor such that the cascode inductor and a notch inductor inductively (e.g., magnetically) couple to each other, introducing a reverse-transmission zero in-band to reduce or eliminate cascode noise contribution and reduce or neutralize gate-drain capacitance of the bottom transistor with reduced or minimal area consumption. For example, a desired or ideal amplifier (e.g., a unilateral amplifier) has only forward transmission gain (S21) and zero reverse transmission gain (S12). However, actual transistors have finite reverse isolation due to internal feedback (e.g., due to the gate-drain capacitance). An external circuit may be used to add feedback to eliminate internal feedback. This method is called neutralization.

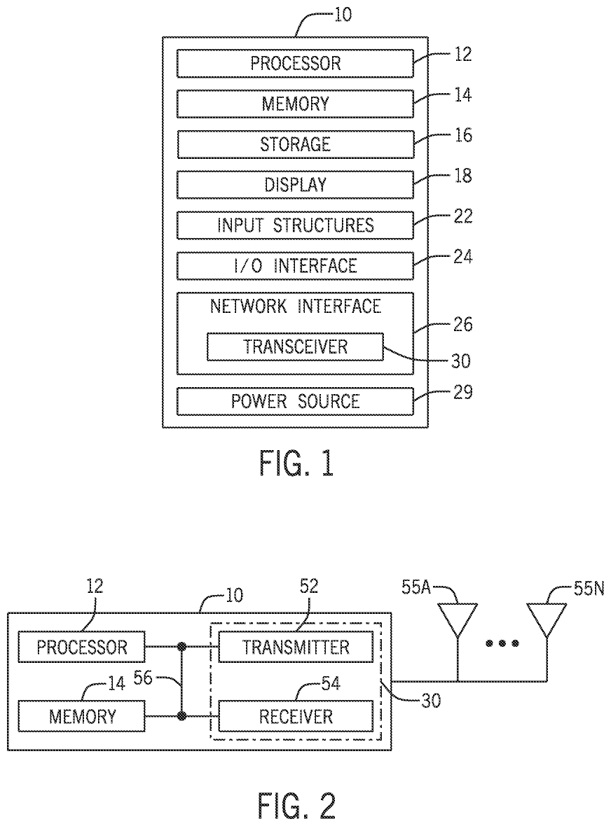

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution® (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

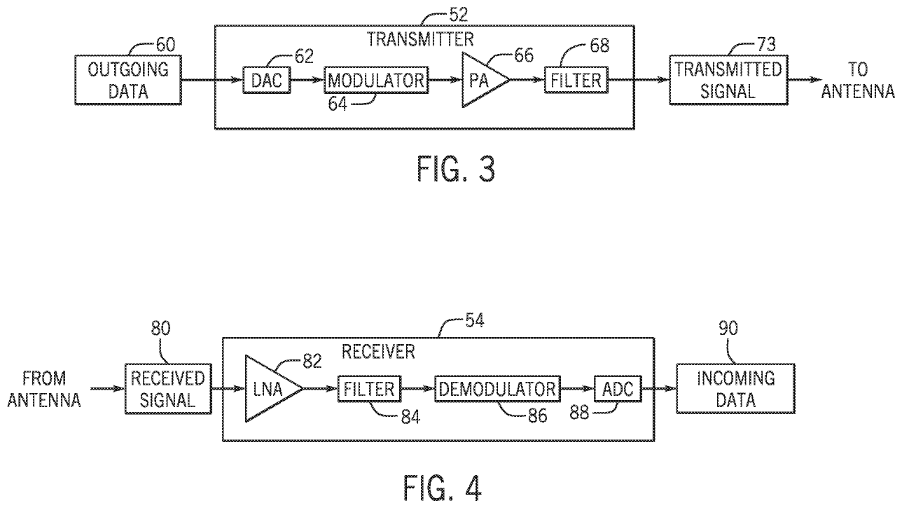

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the received signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The LNA 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

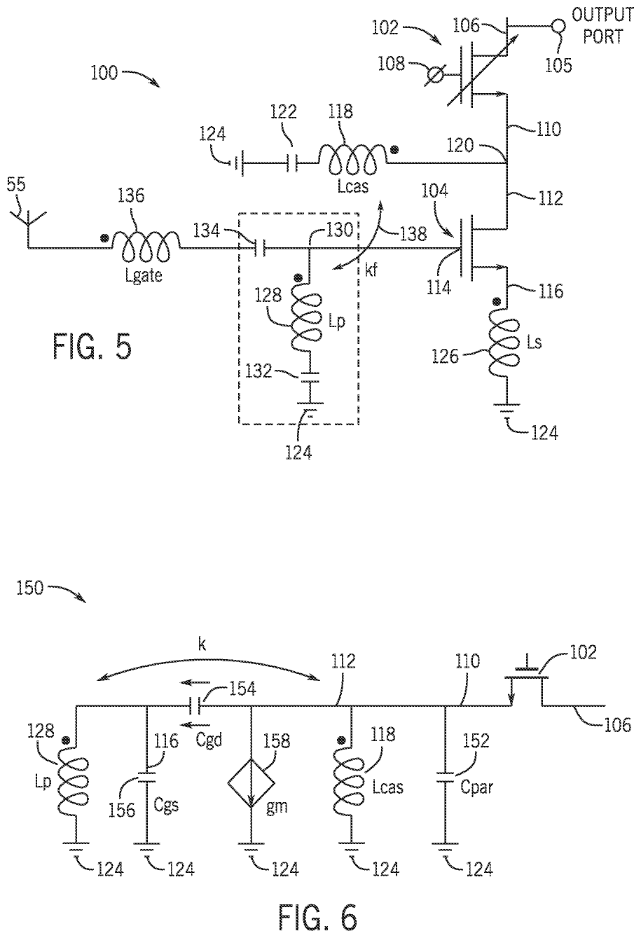

FIG. 5 is a schematic diagram of cascode amplifier 100 configured to reduce or eliminate cascode noise in the cascode amplifier 100 with reduced or minimal area consumption, according to embodiments of the present disclosure. The cascode amplifier 100 may include an LNA, such as the LNA 82 of the receiver 54 or the power amplifier 66 of the transmitter 52. The cascode amplifier 100 includes a cascode transistor 102 and a transconductance transistor 104. The cascode transistor 102 includes a drain terminal 106, a gate terminal 108, and a source terminal 110. An output port 105 may be disposed at the drain terminal 106 of the cascode transistor 102. The transconductance transistor 104 includes a drain terminal 112, a gate terminal 114, and a source terminal 116. The transconductance transistor 104 may receive an input signal at the gate terminal 114 via the antenna 55. That is, the gate terminal 114 may act an input terminal for the input signal from the antenna 55. The source terminal 110 of the cascode transistor 102 is coupled to the drain terminal 112 of the transconductance transistor 104. While the cascode transistor 102 and the transconductance transistor 104 are discussed as metal oxide semiconductor field-effect transistors (MOSFETs) it should be noted that they may include any appropriate type of transistor (e.g., bipolar junction transistor (BJT), junction-gate field-effect transistor (JFET), and so on).

A cascode inductor 118 is coupled at a first terminal to the source terminal 110 of the cascode transistor 102 and the drain terminal 112 of the transconductance transistor 104 at a node 120. The cascode inductor 118 is coupled at a second terminal to a capacitor 122. The capacitor 122 is coupled at a first terminal to the cascode inductor 118 and at a second terminal to ground 124. A source inductor 126 is coupled at a first terminal to the source terminal 116 of the transconductance transistor 104 and coupled at a second terminal to ground 124.

A notch inductor 128 is coupled at a first terminal to the gate terminal 114 of the transconductance transistor 104 via a node 130. The notch inductor 128 is coupled at a second terminal to a capacitor 132. The capacitor 132 is coupled at a first terminal to the notch inductor 128 and at a second terminal to the ground 124. A capacitor 134 is coupled at a first terminal to the gate terminal 114 of the transconductance transistor 104 via the node 130 and coupled at a second terminal to a gate inductor 136. The gate inductor is coupled at a first terminal to the capacitor 134 and at a second terminal to the antenna 55. As may be observed from FIG. 5, the coils of the cascode inductor 118, the source inductor 126, and the notch inductor 128 are wrapped in a first direction while the coils of the gate inductor 136 are wrapped in a second direction opposite of the direction of the coils in the cascode inductor 118, the source inductor 126, and the notch inductor 128. For example, the coils of the cascode inductor 118, the source inductor 126, and the notch inductor 128 may be wrapped in a clockwise direction while the gate inductor 136 is wrapped in a counterclockwise direction, or vice versa. In some embodiments, the cascode amplifier 100 may not include the capacitors 122, 132, and 134. In additional or alternative embodiments, the capacitors 122, 132, and 134 may include direct current (DC) blocking capacitors. For example, DC blocking capacitors may be advantageous in circuits for which the cascode transistor 102 and the transconductance transistor 104 are biased.

In some cascode amplifiers, such as a source degeneration-based cascode LNA, the cascode transistor 102 may contribute excessive noise (e.g., output noise current at the output port 105) at millimeter wave (mmWave) frequencies due to lower output impedance from the transconductance transistor 104. The noise from the cascode transistor 102 may negatively impact performance of the cascode amplifier 100. The output noise current due to the cascode transistor 102 may be expressed in Equation 1 below.

$${i}_{o u t , n}^{2} = {i}_{c a s , n}^{2} \frac{1}{{\vert 1 + {gm}_{2} {Z}_{out} \vert}^{2}} \qquad ( Equation 1 )$$

In Equation 1, i_{out,n}² is the output current at the output port 105; i_{cas,n}² is the mean square current of the drain noise of the cascode transistor 102; gm₂ is the transconductance of the cascode transistor 102; and Zₒᵤₜ is the output impedance of a parallel resistor-capacitor (RC) network where R the inherent output resistance of the cascode transistor 102 and C is the total parasitic capacitance of the cascode amplifier 100, including drain-to-ground and drain-to-gate parasitic capacitance of the transconductance transistor 104 and source-to-gate and source-to-ground parasitic capacitance of the cascode transistor 102.

When an input signal received via the antenna 55 is a low frequency input signal, the output impedance Zₒᵤₜ is dominated by the inherent drain-to-source resistance R_{ds} of the transconductance transistor 104, the noise contribution of the cascode transistor 102 is low or negligible. As the frequency of the input signal received via the antenna 55 increases into mmWave regions (e.g., 30 gigahertz (GHz) to 300 GHz), Zₒᵤₜ is lowered by a low-impedance parasitic capacitance and noise from the cascode transistor 102 begins to increase to the point that the noise from the cascode transistor 102 may negatively impact performance of the cascode amplifier 100.

To improve noise factor of the cascode amplifier 100, improve noise reduction and neutralization, improve amplifier stability and thus maximum available gain (Gmax), coupling between two of the inductors in the cascode amplifier 100 may be facilitated via a determined coupling factor (kf). In an embodiment, the cascode inductor 118 may be inductively (e.g., magnetically) coupled to the notch inductor 128, illustrated by the magnetic coupling path 138. Without coupling of the cascode inductor 118 and the notch inductor 128, a gate-to-drain capacitance (Cgd) of the transconductance transistor 104 may introduce undesirable effects in the cascode amplifier 100.

FIG. 6 is a schematic diagram 150 representing a small signal equivalent circuit model of the cascode amplifier 100, according to embodiments of the present disclosure. The schematic diagram includes the cascode transistor 102, a parasitic capacitance 152 coupled between the source terminal 110 and the ground 124. A parasitic gate-drain capacitance (Cgd) 154 and a parasitic gate-source capacitance 156 may be present at the gate terminal 114 of the transconductance transistor 104. A transconductance 158 of the transconductance transistor 104 is coupled between the drain terminal 112 of the transconductance transistor 104 and the ground 124. The Cgd 154 may be undesirable and adverse for a number of reasons.

For example, without coupling of the cascode inductor 118 and the notch inductor 128, the Cgd of the transconductance transistor 104 may introduce negative resistance when there is inductive impedance at the source terminal 110 of the cascode transistor 102, which may result in narrow band S-parameter and reduced performance with regard to noise matching and impedance matching. Additionally, Cgd 154 may lower the impedance (e.g., the real part of the impedance) of the transconductance transistor 104, which may increase cascode transistor noise. By providing coupling between the cascode inductor 118 and the notch inductor 128, the Cgd 154 as a capacitive coupling path can be cancelled out via the magnetic coupling path 138 having opposite phase of the capacitive coupling path. The coupling factor may be chosen to be negative value or positive value. In some embodiments, the coupling factor may be chosen as positive to more effectively cancel or reduce Cgd 154, suppressing or neutralizing output current noise at the output port 105 resulting from the cascode transistor 102.

Coupling the cascode inductor 118 and the notch inductor 128 may introduce a zero and null the Cgd 154 at a desired frequency, as shown below by Equation 2.

$${f}_{z e r o} = \pm \frac{1}{2 π \sqrt{\frac{Lp ( 1 - {k}^{2} ) nCgd}{k}}} , where n = \sqrt{\frac{Lcas}{Lp}} \qquad ( Equation 2 )$$

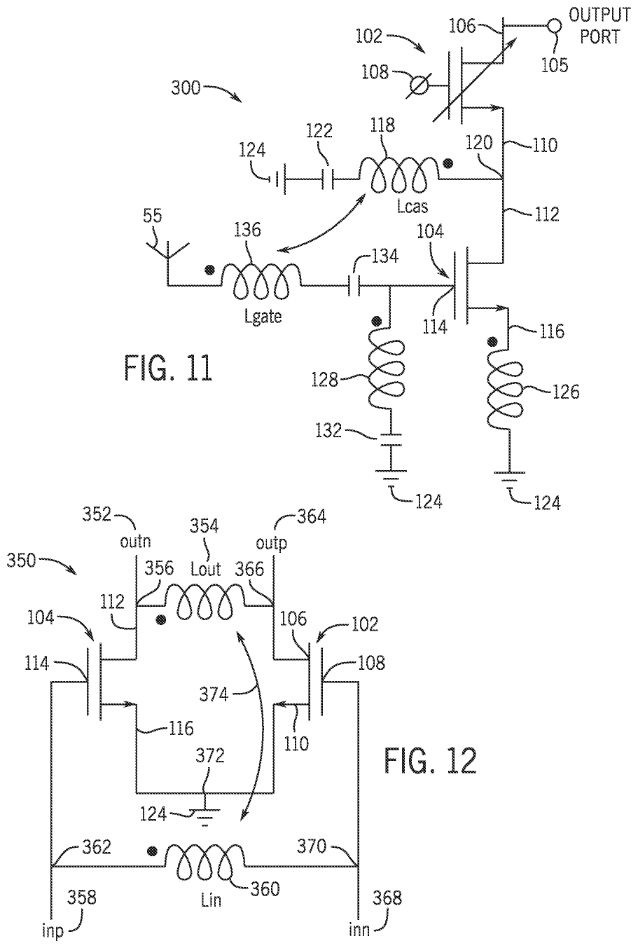

In Equation 2, f is the desired frequency, Lp is the notch inductor 128, Lcas is the cascode inductor 118, and k is the coupling factor. In some embodiments, the cascode inductor 118 and the gate inductor 136 may be inductively coupled to reduce or neutralize cascode noise, as will be discussed with respect to FIG. 11 below.

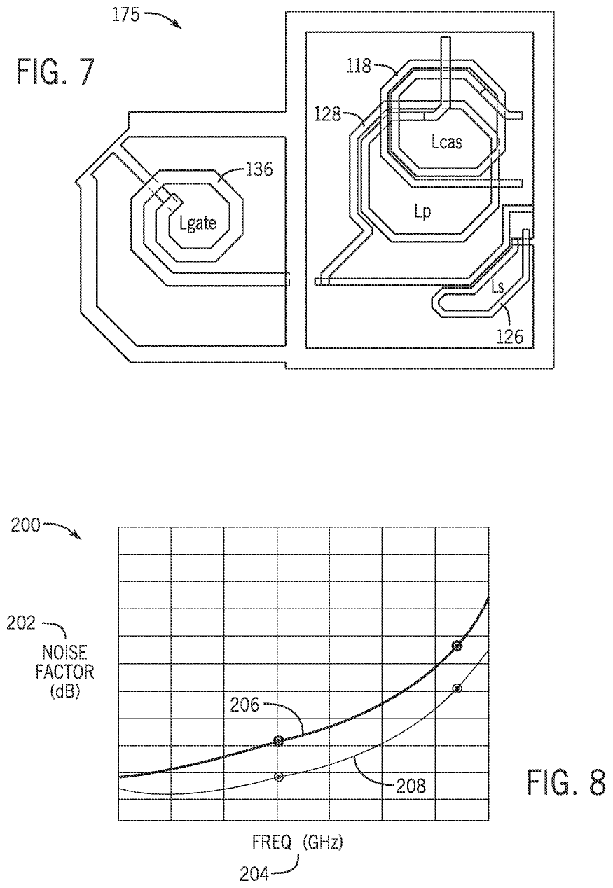

FIG. 7 is a layout diagram 175 illustrating the cascode amplifier 100 discussed with respect to FIG. 5 above, according to embodiments of the present disclosure. The layout diagram 175 depicts the cascode inductor 118, the source inductor 126, the notch inductor 128, and the gate inductor 136, according to embodiments of the present disclosure. In some embodiments, the cascode inductor 118 and the notch inductor 128 may be overlaid and/or intertwined. The overlap between the cascode inductor 118 and the notch inductor 128 may facilitate inductive coupling between the cascode inductor 118 and the notch inductor 128. For instance, one inductor (e.g., the cascode inductor 118) may be disposed on a first circuit board layer while another (e.g., the notch inductor 128) may be disposed on a second circuit board layer, or vice versa. The second circuit board layer may be disposed above, below, or adjacent to the first circuit board layer. In some embodiments, the cascode inductor 118 and the notch inductor 128 may be near one another but not overlapping or intertwined. In other embodiments, the gate inductor 136 and the cascode inductor 118 may be overlaid and/or intertwined to facilitate inductive coupling to reduce or neutralize cascode noise by at least partially canceling Cgd, as will be discussed and illustrated below. While the amplifiers discussed above have been single-ended amplifiers, in still other embodiments, the cascode amplifier 100 may include a differential amplifier, and an input inductor and an output inductor may be overlaid and/or intertwined to facilitate inductive coupling to neutralize cascode noise, as will be discussed and illustrated below.

FIG. 8 is a plot 200 illustrating noise factor of the cascode amplifier 100 as a function of an input signal frequency in a circuit with cascode resonance and neutralization and in a circuit without cascode resonance and neutralization, according to embodiments of the present disclosure. In the plot 200, a vertical or y-axis 202 represents noise factor in decibels (dB) and a horizontal or x-axis 204 represents frequency of an input signal (e.g., signal input to the cascode amplifier 100 via the antenna 55) in GHz. A curve 206 illustrates noise factor as a function of input signal frequency in a cascode amplifier without cascode resonance a neutralization. That is, the curve 206 illustrates the noise factor in the cascode amplifier 100 wherein the cascode inductor 118 and the notch inductor 128 are not inductively coupled. A curve 208 illustrates noise factor as a function of the input signal frequency in a cascode amplifier with cascode resonance and neutralization. That is, the curve 208 illustrates the noise factor in the cascode amplifier 100 wherein the cascode inductor 118 and the notch inductor 128 are inductively coupled, as is illustrated with respect to FIG. 5. As may be observed from the plot 200, the curve 208 represents a lower noise factor as a function of frequency than the curve 206. Accordingly, it may be appreciated that inductively coupling the cascode inductor 118 and the notch inductor 128 may reduce noise factor of the cascode amplifier 100, improving performance of the cascode amplifier 100.

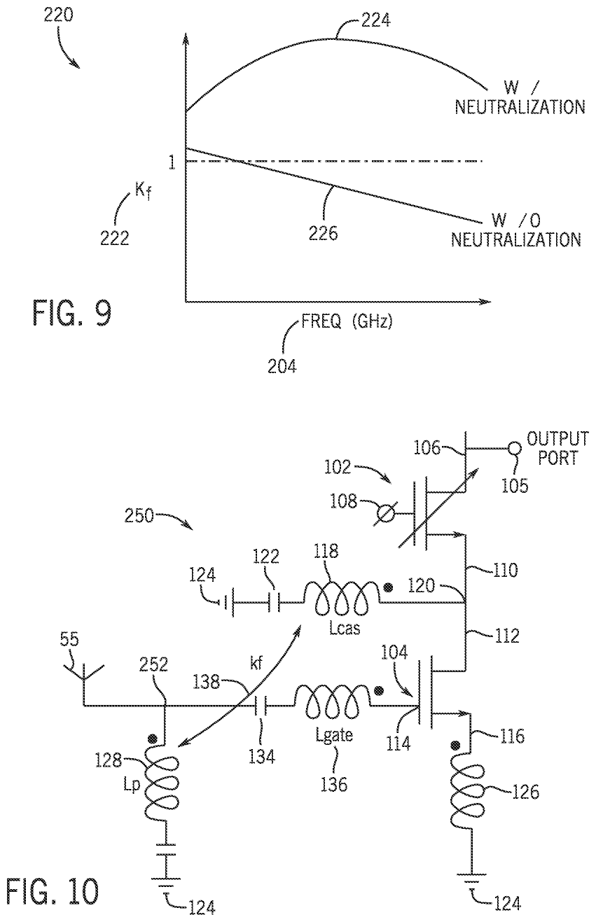

Establishing coupling between two of the cascode inductor 118 and the notch inductor 128 in the cascode amplifier 100 may improve amplifier stability and thus maximum available gain (Gmax) in the cascode amplifier 100, in addition to noise reduction and neutralization. FIG. 9 is a plot 22 illustrating a stability factor kf as a function of input frequency in a circuit with neutralization and in a circuit without neutralization, according to embodiments of the present disclosure. The plot 220 includes the x-axis 204 representing input frequency and a y-axis 222 representing the stability factor kf. A curve 224 represents the stability factor in circuits wherein a coupling factor is established between two inductors to improve noise neutralization. That is, the curve 406 illustrates stability factor in the cascode amplifier 100 wherein the cascode inductor 118 and the notch inductor 128 are inductively coupled, as is illustrated with respect to FIG. 5. A curve 226 represents the stability factor in an amplifier without neutralization. That is, the curve 226 illustrates the stability factor in circuits wherein there is no coupling between inductors (e.g., the cascode inductor 118 and the notch inductor 128). It should be noted that a stability factor greater than or equal to 1 indicates stability, while a stability factor less than 1 indicates instability. It may be observed from the plot 220 that the curve 224 remains above 1 as frequency increases (e.g., indicating amplifier stability) while the curve 226 drops below 1 (e.g., becomes unstable) as frequency increases. Accordingly, it may be appreciated that inductively coupling the cascode inductors as discussed above with respect to FIG. 5 may improve amplifier stability and thus improve maximum available gain.

Alternative embodiments for the cascode amplifier 100 may be used to reduce or neutralize noise. FIG. 10 illustrates a schematic diagram of an alternative cascode amplifier 250, according to embodiments of the present disclosure. The cascode amplifier 250 includes the same components as the cascode amplifier 100 and is otherwise similar to the cascode amplifier 100, except that the notch inductor 128 is coupled directly to the input of the antenna 55.

In the cascode amplifier 250, the gate inductor 136 is coupled directly to the gate terminal 114 of the transconductance transistor 104 at a first terminal of the gate inductor 136 and is coupled to the capacitor 134 at a second terminal of the gate inductor 136. Similarly to FIG. 5, the coil windings of the gate inductor 136 in the cascode amplifier 250 may be opposite that of the coil windings of the cascode inductor 118, the source inductor 126, and the notch inductor 128. For example, the coils of the cascode inductor 118, the source inductor 126, and the notch inductor 128 may be wrapped in a clockwise direction while the gate inductor 136 is wrapped in a counterclockwise direction, or vice versa. The capacitor 134 is coupled at a first terminal to the gate inductor 136 and at a second terminal to the antenna 55 and a first terminal of the notch inductor 128 via a node 252. The notch inductor 128 is coupled at the first terminal to the antenna and the second terminal of the capacitor 134 via the node 252 and coupled at a second terminal to ground 124. In some embodiments, a capacitor (e.g., a DC blocking capacitor) may be coupled between the notch inductor 128 and the ground 124. It should be noted that the cascode amplifier 250 may otherwise operate similarly or identically to the cascode amplifier 100, in that the cascode inductor 118 and the notch inductor 128 may overlap, be intertwined, or be near enough to each other that inductive (e.g., magnetic) coupling may be facilitated to reduce or neutralize noise caused by the cascode transistor 102, as previously discussed with respect to FIG. 5. Additionally, in some embodiments, cascode noise may be reduced or neutralized via coupling between the cascode inductor 118 and the gate inductor 136.

As previously mentioned, other alternative embodiments of the cascode amplifier 100 may include inductive coupling between other inductors to reduce or neutralize noise caused by the cascode transistor 102. FIG. 11 illustrates a schematic diagram of a cascode amplifier 300, wherein the cascode amplifier 300 is configured to reduce or neutralize noise caused by the cascode transistor 102 via inductive coupling between the cascode inductor 118 and the gate inductor 136, according to embodiments of the present disclosure. It may be appreciated that the cascode amplifier 300 includes the same components and structure as the cascode amplifier 100 discussed with respect to FIG. 5. However, the cascode amplifier 300 may reduce or neutralize cascode noise via inductive coupling of the cascode inductor 118 and the gate inductor 136, as indicated by the magnetic coupling path 302. To induce inductive coupling, the cascode inductor 118 and the gate inductor 136 may be overlapped, intertwined, or disposed sufficiently near each other, similarly as to what was discussed with respect to FIG. 7. Coupling the cascode inductor 118 and the gate inductor 136 may reduce or neutralize noise resulting from the cascode transistor 102 by at least partially canceling Cgd of the transconductance transistor 104, improving overall performance of the cascode amplifier 300, similarly to the improvements discussed with respect to FIGS. 5-8.

FIG. 12 is a schematic diagram of a differential cascode amplifier 350 illustrating how inductive coupling may be used to reduce or neutralize cascode noise, according to embodiments of the present disclosure. The differential cascode amplifier 350 includes the transconductance transistor 104 and the cascode transistor 102. The drain terminal 112 of the transconductance transistor 104 is coupled to an output terminal 352 of the differential cascode amplifier 350 and an output inductor 354 via a node 356. The gate terminal 114 is coupled to an input terminal 358 of the differential cascode amplifier 350 and an input inductor 360 via a node 362. The source terminal 116 is coupled to ground 124. The drain terminal 106 of the cascode transistor 102 is coupled to an output terminal 364 and the output inductor 354 via a node 366. The gate terminal 108 is coupled to an input terminal 368 and the input inductor 360 via a node 370. The source terminal 110 is coupled to the ground 124 and the source terminal 116 at a node 372.

As may be observed from the differential cascode amplifier 350, the coil windings of the input inductor 360 and the output inductor 354 may be wound in the same direction (e.g., such that the coils of the input inductor 360 and the output inductor 354 are both wound in the counterclockwise or the clockwise direction). In additional or alternative embodiments, the coils may be wound in opposite directions. For example, the coils of the output inductor 354 may be wound in the clockwise direction while the coils of the input inductor 360 may be wound in the counterclockwise direction, or vice versa. The output inductor 354 and the input inductor 360 may be disposed such that inductive coupling may be facilitated. That is, the output inductor 354 and the input inductor 360 may overlap, be intertwined, or be disposed sufficiently near each other that the may be configured to inductively couple via a magnetic coupling path 374. Similarly to the inductive coupling discussed previously, a coupling factor kf may be chosen to reduce or cancel Cgd of the transconductance transistor 104 to reduce or neutralize noise resulting from the cascode transistor 102. In some embodiments, a positive coupling factor may effectively reduce or null the Cgd. By inductively coupling the input inductor 360 the output inductor 354, overall noise within the differential cascode amplifier 350 may be reduced or neutralized, enhancing overall performance of the differential cascode amplifier 350. The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A device, comprising:
a plurality of antennas;
a transmitter coupled to the plurality of antennas; and
a receiver coupled to the plurality of antennas, the receiver comprising
a low-noise amplifier (LNA), comprising
a first transistor,
a first inductor coupled to a first source terminal of the first transistor;
a second transistor comprising
a drain terminal coupled to the first source terminal of the first transistor and the first inductor,
a gate terminal coupled to at least one antenna of the plurality of antennas and comprising an input terminal, and
a second source terminal, and
a second inductor coupled to the gate terminal of the second transistor, the second inductor overlapping the first inductor.

2. The device of claim 1, comprising a third inductor coupled to the second source terminal.

3. The device of claim 2, comprising a capacitor coupled between the third inductor and a ground.

4. The device of claim 1, comprising a third inductor coupled to the at least one of the plurality of antennas.

5. The device of claim 4, comprising a capacitor coupled to the third inductor at a first capacitor terminal and coupled to the gate terminal and the second inductor at a second capacitor terminal.

6. The device of claim 1, wherein a capacitor is coupled between the first inductor and a ground.

7. The device of claim 1, wherein a capacitor is coupled between the second inductor and a ground.

8. The device of claim 7, wherein the capacitor comprises a direct current blocking capacitor.

9. The device of claim 1, wherein the LNA comprises a single-ended amplifier.

10. A low-noise amplifier (LNA), comprising:
a first transistor;
a first inductor coupled to a first source terminal of the first transistor and coupled to ground;
a second transistor comprising
a drain terminal coupled to the first source terminal of the first transistor and the first inductor, and
a gate terminal comprising an input terminal, and
a second inductor coupled to the gate terminal of the second transistor, the second inductor configured to inductively couple to the first inductor.

11. The LNA of claim 10, comprising a third inductor coupled to the gate terminal of the second transistor at a first inductor terminal and coupled to a capacitor at a second inductor terminal.

12. The LNA of claim 11, wherein the second inductor is coupled between the capacitor and an input antenna.

13. The LNA of claim 10, comprising a third inductor coupled to a second source terminal of the second transistor.

14. The LNA of claim 13, comprising a direct current blocking capacitor coupled between the third inductor and the ground.

15. An amplifier, comprising:
a first transistor, comprising
a first source terminal,
a second transistor, comprising
a drain terminal,
a gate terminal, wherein the gate terminal is configured as an input terminal, and
a second source terminal,
a first inductor coupled at a first inductor terminal to the first source terminal and the drain terminal; and
a second inductor coupled at a third inductor terminal to the gate terminal and at a second inductor terminal to a capacitor, wherein the second inductor is configured to couple to the first inductor.

16. The amplifier of claim 15, comprising a third inductor coupled to the gate terminal.

17. The amplifier of claim 16, wherein the third inductor is between an input antenna and an additional capacitor.

18. The amplifier of claim 17, wherein the capacitor is coupled to the second inductor and the gate terminal via the third inductor terminal.

19. The amplifier of claim 15, wherein the first transistor, the second transistor, or both comprise a metal oxide semiconductor field-effect transistor (MOSFET).

20. The amplifier of claim 15, wherein the first inductor and the second inductor are configured to couple via a coupling factor, wherein the coupling factor comprises a positive value.
